(19) United States
(12) Patent Application Publication
(10) Pub. No.: US 2008/0180381 A1
(43) Pub. Date: Jul. 31, 2008

(54) PULSE WIDTH MODULATION DIMMING CONTROL METHOD AND DISPLAY APPARATUS HAVING PULSE WIDTH MODULATION DIMMING CONTROL FUNCTION

(75) Inventors: Jin-gil JEONG, Seoul (KR); Joon-hyun YANG, Suwon-si (KR); Agarwal PANKAJ, Suwon-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD., Suwon-si (KR)

(21) Appl. No.: 11/832,191

(22) Filed: Aug. 1, 2007

(30) Foreign Application Priority Data
Jan. 25, 2007 (KR) 10-2007-0007942

(51) Int. Cl. G09G 3/36; H03K 7/08

(52) U.S. Cl. 345/99; 332/109

(57) ABSTRACT

A pulse width modulation (PWM) dimming control method and a display apparatus having a PWM dimming control function are provided. The method includes setting a PWM period of a group lighting block based on a state of both a first gate line and a last gate line among a plurality of gate lines corresponding to the group lighting block; and controlling PWM dimming of the group lighting block based on the set PWM period. The display apparatus includes a timing controller which determines a pulse width modulation (PWM) period of a group lighting block based on a state of both a first gate line and a last gate line among a plurality of gate lines corresponding to the group lighting block; and a PWM dimming controller which generates a PWM signal for controlling PWM dimming based on the determined PWM period.

### CROSS-REFERENCE TO RELATED PATENT APPLICATION

This application claims priority from Korean Patent Application No. 10-2007-0007942, filed on Jan. 25, 2007, in the Korean Intellectual Property Office, the disclosure of which is incorporated herein in its entirety by reference.

### BACKGROUND OF THE INVENTION

1. Field of the Invention

Methods and apparatuses consistent with the present invention relate to a pulse width modulation (PWM) dimming control, and more particularly, to PWM dimming control using a light-emitting diode (LED) back light unit.

2. Description of the Related Art

An LED back light unit is a device that illuminates a display panel such as a thin film transistor-liquid crystal display (TFT-LCD) panel using an LED as a light source. The TFT-LCD panel is a light-receiving display device that forms images using external light, and thus the TFT-LCD panel uses a fluorescent lamp for irradiating the backside thereof. The LED back light unit functions as this fluorescent lamp.

The LED back light unit controls the brightness of LEDs using a dimming method. The dimming method includes an analog dimming method and a pulse width modulation (PWM) dimming method. The analog dimming method adjusts the current supplied to each LED included in the LED back light unit to control the brightness of the LED back light unit. That is, when the current supplied to each LED included in the LED back light unit is reduced by half through the analog dimming method, the brightness of the LED back light unit is decreased by half. The PWM dimming method adjusts the on-off time ratio of each LED included in the LED back light unit in response to a PWM signal to control the brightness of the LED back light unit. That is, when a PWM signal having an on-off time ratio of 4:1 is supplied to LEDs included in the LED back light unit, the brightness of the LED back light unit reaches 80% of a maximum brightness.

A scan signal applied to gate lines G1 through Gn of a related art TFT-LCD panel has a cycle as illustrated in FIG. 1. When the LED back light unit is operated in a scan back light mode that sequentially turns on LEDs line by line, PWM dimming is controlled in synchronization with a TFT gate ON time. Accordingly, the PWM period of each LED included in the LED back light unit can be set to a period from a falling edge of the gate ON time to a falling edge of the next gate ON time.

When the LED back light unit is operated in a group lighting back light mode that simultaneously turns on LEDs in a predetermined block and a predetermined block includes five lines as illustrated in FIG. 2, PWM dimming is controlled in synchronization with the TFT gate ON time of the first gate line included in the predetermined block. Accordingly, the PWM period of the predetermined block can be set to a period from a falling edge of the gate ON time of the first line included in the predetermined block to a falling edge of the next gate ON time of the first line, as illustrated in FIG. 2.

However, when the LED back light unit is operated in the group lighting back light mode, PWM periods for controlling PWM dimming of the respective gate lines included in a predetermined block are different. This is because the gate lines included in the predetermined block have different gate ON-OFF times. That is, a gate line G1 illustrated in FIG. 2 has the longest PWM period and a gate line G5 illustrated in FIG. 2 has the shortest PWM period.

As described above, gate lines included in a predetermined block have different PWM periods, and thus a luminance difference and a gradation unbalance between horizontal lines on a display panel are generated.

### SUMMARY OF THE INVENTION

The present invention provides a PWM dimming control method and a display apparatus having a PWM dimming control function for preventing a luminance difference and a gradation unbalance between horizontal lines on a display panel when an LED back light is operated in the group lighting back light mode.

According to an aspect of the present invention, there is provided a PWM dimming control method in a display apparatus including a display panel and a back light unit irradiating the display panel, the method comprising setting the PWM period of a group lighting block such that the PWM period does not correspond to the gate ON time of each of gate lines corresponding to the group lighting block in the back light unit; and controlling PWM dimming of the group lighting block based on the set PWM period.

The setting of the PWM period may include setting a period from the time after the gate corresponding to the last gate line among gate lines corresponding to the group lighting block is turned on to the time before the gate corresponding to the first gate line among the gate lines corresponding to the group lighting block is turned on as the PWM period.

The setting of the PWM period comprises setting a period from a falling edge of a gate ON time of the last gate line among the plurality of gate lines corresponding to the group lighting block to a rising edge of a gate ON time of the first gate line among the plurality of gate lines corresponding to the group lighting block as the PWM period.

According to another aspect of the present invention, there is provided a display apparatus including a display panel and a back light unit irradiating the display panel, the apparatus comprising a timing controller which determines a PWM period of a group lighting block of the back light unit such that the PWM period does not correspond to the gate ON time of each of gate lines of the display panel, which correspond to the group lighting block; and a PWM dimming controller which generates a PWM signal for controlling PWM dimming based on the determined PWM period.

The timing controller may determine a period from the time after the gate corresponding to the last gate line among gate lines corresponding to the group lighting block is turned on to the time before the gate corresponding to the first gate line among the gate lines corresponding to the group lighting block is turned on as the PWM period.

According to another aspect of the present invention, there is provided a pulse width modulation (PWM) dimming control method comprising: setting a PWM period of a group lighting block based on a state of both a first gate line and a last gate line among a plurality of gate lines corresponding to the group lighting block; and controlling PWM dimming of the group lighting block based on the set PWM period.

### BRIEF DESCRIPTION OF THE DRAWINGS

The above and other aspects of the present invention will become more apparent by describing in detail exemplary embodiments thereof with reference to the attached drawings in which:

FIG. 1 illustrates a relationship between a cycle of a scan signal applied to gate lines of a related art TFT-LCD panel and a PWM period when an LED back light unit is operated in a scan back light mode;

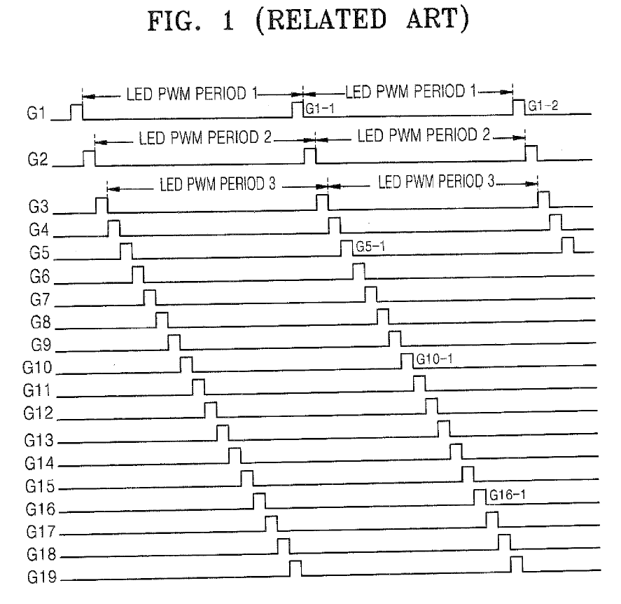

FIG. 2 illustrates a relationship between a cycle of the scan signal applied to the gate lines of a related art TFT-LCD panel and a PWM period when the LED back light unit is operated in a group lighting back light mode;

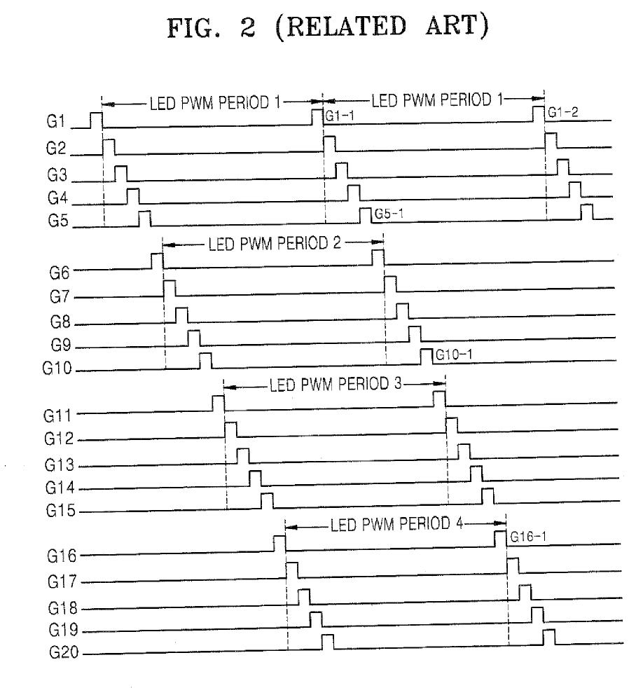

FIG. 3 is a block diagram of a display apparatus according to an exemplary embodiment of the present invention;

FIG. 4 illustrates a relationship between a cycle of a scan signal applied to gate lines of an LCD panel illustrated in FIG. 3 and a PWM period determined according to an exemplary embodiment of the present invention;

FIG. 5 illustrates a relationship between an LED back light unit and the LCD panel illustrated in FIG. 3 based on the relationship illustrated in FIG. 4; and

FIG. 6 is a flow chart illustrating a PWM dimming control method according to an exemplary embodiment of the present invention.

### DETAILED DESCRIPTION OF EXEMPLARY EMBODIMENTS OF THE PRESENT INVENTION

The present inventive concept will now be described more fully with reference to the accompanying drawings, in which exemplary embodiments of the invention are shown. The present inventive concept may, however, be embodied in many different forms and should not be construed as being limited to the exemplary embodiments set forth herein; rather, these exemplary embodiments are provided so that this disclosure will be thorough and complete, and will fully convey the concept of the invention to those skilled in the art. Throughout the drawings, like reference numerals refer to like elements.

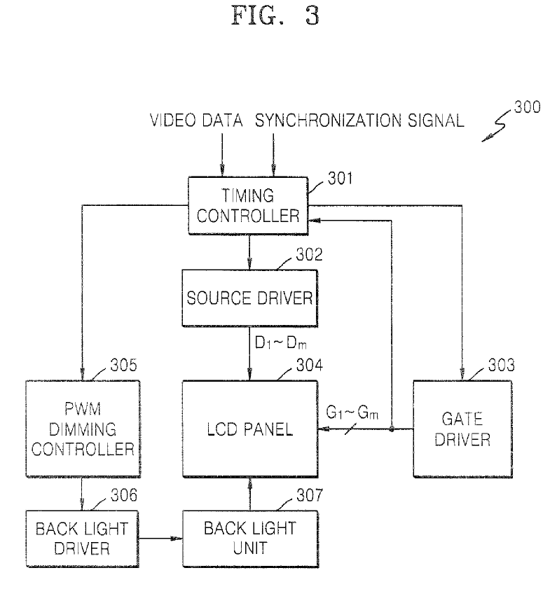

FIG. 3 is a block diagram of a display apparatus 300 according to an exemplary embodiment of the present invention. Referring to FIG. 3, the display apparatus 300 includes a timing controller 301, a source driver 302, a gate driver 303, an LCD panel 304, a PWM dimming controller 305, a back light driver 306, and a back light unit 307.

The timing controller 301 receives video data corresponding to an image that will be displayed on the LCD panel 304 and a synchronization signal of the video data, provides a data control signal to the source driver 302 using the video data, and provides a gate control signal to the gate driver 303 using the synchronization signal. In addition, the timing controller 301 determines a PWM period for PWM dimming control based on a scan signal generated through gate lines by the gate driver 303 in response to the gate control signal. When the back light unit 307 is operated in a group lighting back light mode, the timing controller 301 determines the PWM period of a group lighting block such that the PWM period does not correspond to the gate ON times of gate lines corresponding to the group lighting block. That is, the PWM period is set based on a state of both a first gate line and a last gate line among a plurality of gate lines corresponding to the group lighting block. The group lighting block corresponds to the above-described block and the group lighting block is previously set.

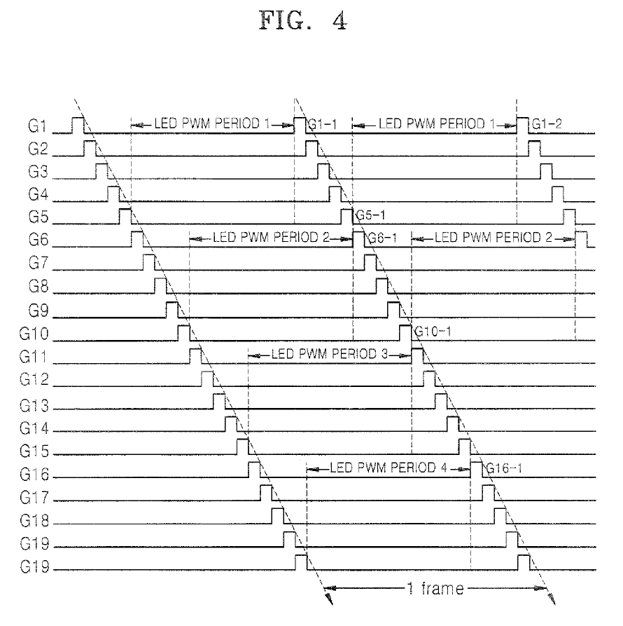

When the group lighting block includes, for example, five gate lines, as illustrated in FIG. 4, the timing controller 301 checks the gate ON time of each of the five gate lines based on the scan signal generated by the gate driver 304. Specifically, in the case of an example of a first group lighting block corresponding to gate lines G1 through G5, the timing controller 301 determines a period from a falling edge of the gate ON time of the last gate line G5 of the first group lighting block to a rising edge of the gate ON time G1-1 of the first gate line G1 of the first group lighting block as the PWM period (LED PWM period 1) of the first group lighting block.

In the case of a second group lighting block corresponding to gate lines G6 through G10, the timing controller 301 determines a period from a falling edge of the gate ON time of the last gate line G10 of the second group lighting block to a rising edge of the first gate line G6 of the second group lighting block as the PWM period (LED PWM period 2) of the second group lighting block.

In the case of a third group lighting block corresponding to gate lines G11 through G15, the timing controller 301 determines a period from a falling edge of the gate ON time of the last gate line G15 of the third group lighting block to a rising edge of the first gate line G11 of the third group lighting block as the PWM period (LED PWM period 3) of the third group lighting block.

In the case of a fourth group lighting block corresponding to gate lines G16 through G20, the timing controller 301 determines a period from a falling edge of the gate ON time of the last gate line G20 of the fourth group lighting block to a rising edge of the first gate line G16 of the fourth group lighting block as the PWM period (LED PWM period 4) of the fourth group lighting block.

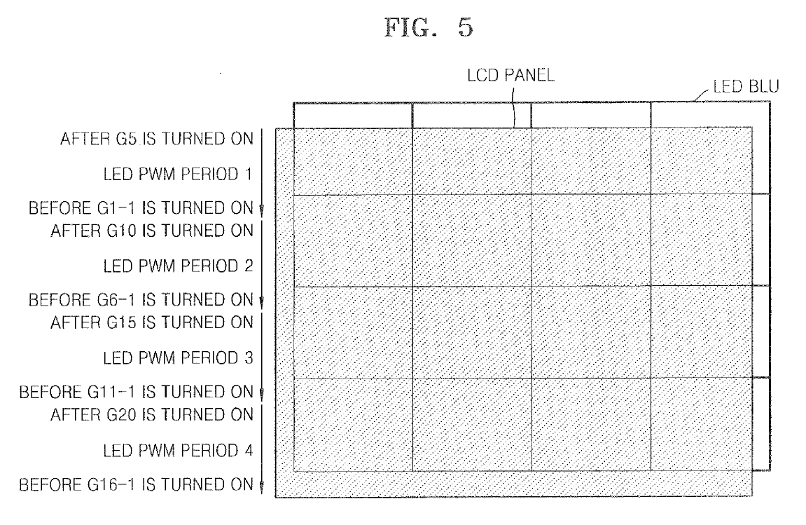

FIG. 4 illustrates a relationship between the cycle of a scan signal applied to gate lines of the display apparatus illustrated in FIG. 3 and the PWM periods determined as described above according to an exemplary embodiment of the present invention. FIG. 5 illustrates the relationship between the LED back light unit 307 and the LCD panel 304 illustrated in FIG. 3 based on the relationship illustrated in FIG. 4.

In FIGS. 3, 4 and 5, the gate ON time denotes the time when a gate of a thin film transistor included in the LCD panel 304 is turned on.

The source driver 302 provides video data RGB corresponding to one line to data lines D1 through Dm for every horizontal period in response to the data control signal provided by the timing controller 301.

The gate driver 304 generates the scan signal for every horizontal period and sequentially provides the scan signal to the gate lines G1 through Gn in response to the gate control signal provided by the timing controller 301.

The LCD panel 304 includes a plurality of liquid crystal cells (not shown) respectively arranged at intersections of the data lines D1 through Dm and the gate lines G1 through Gn in a matrix form. Thin film transistors respectively formed at the liquid crystal cells provide pixel signals, which are supplied from the data lines D1 through Dm in response to the scan signal provided to the gate lines G1 through Gn, to the liquid crystal cells. The liquid crystal cells respectively include storage capacitors. A storage capacitor is formed between a pixel electrode of a liquid crystal cell and a gate line or between the pixel electrode and a common electrode line and maintains the voltage of the liquid crystal cell uniform.

The PWM dimming controller 305 outputs a PWM signal for controlling PWM dimming of each group lighting block in the PWM period of each group lighting block, which is determined by the timing controller 301. The ON-OFF time ratio of the PWM signal is set by the timing controller 301. The timing controller 301 can determine the ON-OFF time ratio of the PWM signal based on the luminance of input video data. For example, the timing controller 301 determines the PWM signal such that its ON period is shorter than its OFF period when the luminance of the input video data is low and determines the PWM signal such that its ON period is equal to its OFF period when the luminance of the input video data is intermediate. In addition, the timing controller 301 determines the PWM signal such that its ON period is longer than its OFF period when the luminance of the input video data is high. The ON-OFF time ratio of the PWM signal is equal to the ON-OFF time ratio of LEDs included in each group lighting block.

The back light driver 306 turns ON and OFF LEDs included in the back light unit 307 for each group lighting block based on the PWM signal supplied from the PWM dimming controller 305. Furthermore, the back light driver 306 may generate a driving current of the back light unit 307.

The back light unit 307 is an LED back light unit and LEDs included therein are turned ON and OFF by the back light driver 306 for each group lighting block to generate R, G and B lights. To achieve this, the back light unit 307 includes a red back light emitting red light, a green back light emitting green light and a blue back light emitting blue light.

The timing controller 301 and the PWM dimming controller 305 can be modified in such a manner that the operation of determining the PWM period, performed by the timing controller 301, is carried out by the PWM dimming controller 305. If the PWM dimming controller 305 determines the PWM period, the display apparatus 300 can be modified such that the timing controller 301 provides a gate line scan pulse signal generated by the gate driver 304 to the PWM dimming controller 305.

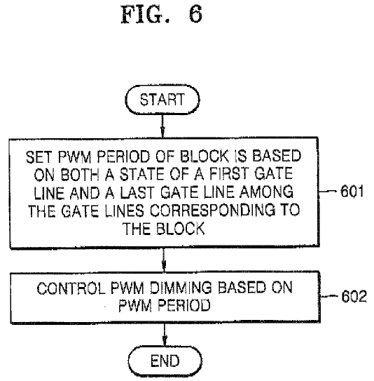

FIG. 6 is a flow chart of a PWM dimming control method according to an exemplary embodiment of the present invention. Referring to FIGS. 3 and 6, the timing controller 301 determines a PWM period of a group lighting block in the back light unit 307 such that the PWM period does not correspond to the gate ON time of each of gate lines corresponding to the group lighting block in operation 601. That is, the PWM period is set based on a state of both a first gate line and a last gate line among a plurality of gate lines corresponding to the group lighting block. Specifically, the timing controller 301 determines a period from a time after a gate corresponding to a last gate lines among gate lines corresponding to the group lighting block is turned ON to a time before a gate corresponding to a first gate line among the gate lines corresponding to the group lighting block is turned ON as the PWM period of the group lighting block.

Subsequently, PWM dimming of the group lighting block is controlled based on the determined PWM period in operation 602.

A program for executing the PWM dimming control method according to an exemplary embodiment of the present invention can also be embodied as computer readable code on a computer readable recording medium. The computer readable recording medium may be a data storage device that can store data which can be thereafter read by a computer system. Examples of the computer readable recording medium include read-only memory (ROM), random-access memory (RAM), CD-ROMs, magnetic tapes, floppy disks, optical data storage devices, and carrier waves (such as data transmission through the Internet). The computer readable recording medium can also be distributed over network coupled computer systems so that the computer readable code is stored and executed in a distributed fashion.

As described above, exemplary embodiments of the present invention determine the PWM period of a block such that the PWM period does not correspond to the gate on time of each of gate lines included in the block when an LED back light unit is operated in a group lighting back light mode. Accordingly, exemplary embodiments of the present invention can control PWM dimming without causing luminance difference and gradation unbalance between horizontal lines on a display panel.

While the present inventive concept has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A pulse width modulation (PWM) dimming control method comprising:
setting a PWM period of a group lighting block based on a state of both a first gate line and a last gate line among a plurality of gate lines corresponding to the group lighting block; and
controlling PWM dimming of the group lighting block based on the set PWM period.

2. The PWM dimming control method of claim 1, wherein the setting of the PWM period comprises setting a period from a time after the last gate line among the plurality of gate lines corresponding to the group lighting block is turned ON to a time before the first gate line among the plurality of gate lines corresponding to the group lighting block is turned ON as the PWM period.

3. The PWM dimming control method of claim 1, wherein the setting of the PWM period comprises setting a period from a falling edge of a gate ON time of the last gate line among the plurality of gate lines corresponding to the group lighting block to a rising edge of a gate ON time of the first gate line among the plurality of gate lines corresponding to the group lighting block as the PWM period.

4. A display apparatus comprising:
a timing controller which determines a pulse width modulation (PWM) period of a group lighting block based on a state of both a first gate line and a last gate line among a plurality of gate lines corresponding to the group lighting block; and
a PWM dimming controller which generates a PWM signal for controlling PWM dimming based on the determined PWM period.

5. The display apparatus of claim 4, further comprising:
a display panel; and
a back light unit which irradiates the display panel.

6. The display apparatus of claim 4, wherein the timing controller determines a period from a time after the last gate line among a plurality of gate lines corresponding to the group lighting block is turned ON to a time before the first gate line among the gate lines corresponding to the group lighting block is turned ON as the PWM period.

7. The display apparatus of claim 4, wherein the timing controller determines a period from a falling edge of a gate ON time of the last gate line among the plurality of gate lines corresponding to the group lighting block to a rising edge of a gate ON time of the first gate line among the plurality of gate lines corresponding to the group lighting block as the PWM period.

8. A computer readable recording medium storing a program for executing the method comprising:
setting a pulse width modulation (PWM) period of a group lighting block based on a state of both a first gate line and a last gate line among a plurality of gate lines corresponding to the group lighting block; and
controlling PWM dimming of the group lighting block based on the set PWM period.
